(19) United States
(12) Patent Application Publication
(10) Pub. No.: US 2007/0153580 A1
(43) Pub. Date: Jul. 5, 2007

(54) MEMORY ARRANGEMENT, MEMORY DEVICE, METHOD FOR SHIFTING DATA FROM A FIRST MEMORY DEVICE TO A SECOND MEMORY DEVICE, AND COMPUTER PROGRAM ELEMENT

(75) Inventors: Achim Luft, Braunschweig (DE); Andreas Schmidt, Braunschweig (DE); Sabine van Niekerk, Salzgitter-Lebenstedt (DE)

Correspondence Address: DICKSTEIN SHAPIRO LLP, 1177 AVENUE OF THE AMERICAS 6TH AVENUE, NEW YORK, NY, 10036-2714, US

(73) Assignee: INFINEON TECHNOLOGIES AG, Munich (DE)

(21) Appl. No.: 11/620,551

(22) Filed: Jan. 5, 2007

(30) Foreign Application Priority Data
Jan. 5, 2006 (DE) 10 2006 000 930.4

(51) Int. Cl. G11C 11/34

(52) U.S. Cl. 365/185.19

(57) ABSTRACT

Memory device having a memory for storage of data to be shifted, as well as a unit for encryption of data based on an asymmetric encryption method using a public key of a second memory device, to which the data which is to be shifted and is stored in the memory is to be shifted. In addition, a deletion unit is provided for deletion from the memory of the stored data which is to be shifted, once the data which is to be shifted and is encrypted with the public cryptographic key of the second memory device has been formed. A copying unit copies the shift message to the second memory device or to a third memory device, with the data no longer being available in the first memory from a time before the copying of the shift message to the second memory device or to the third memory device.

### CROSS-REFERENCE TO RELATED APPLICATION

This application claims priority to German Patent Application Serial No. 10 2006 000 930.4-53, which was filed Jan. 5, 2006, and is incorporated herein by reference in its entirety.

### BACKGROUND OF THE INVENTION

The invention relates to a memory arrangement, memory devices, methods for shifting of data from a first memory device to a second memory device, and computer program elements.

An operation which is referred to as “shifting” is frequently carried out in data-processing appliances on a data record, which is also referred to in the following text as data, stored in a memory device. During this operation, the stored data is shifted from one memory location, and thus a first memory device, to a different memory location, and thus to a second memory device. Secure shift methods, in which impermissible copying of the data can be prevented may be desirable, for example in the case of data whose originator rights are protected.

### DESCRIPTION OF THE FIGURES

In the figures:

FIG. 1 shows a memory arrangement according to one exemplary embodiment of the invention;

FIG. 2 shows a message flowchart, illustrating the message flow during shifting of data from a first memory device to a second memory device, according to one exemplary embodiment of the invention;

FIG. 3 shows a flowchart illustrating a method for encryption of the data according to one exemplary embodiment of the invention;

FIG. 4 shows a flowchart illustrating a method for decryption of the encrypted data according to one exemplary embodiment of the invention;

FIG. 5 shows a block diagram illustrating the asymmetric encryption method in one exemplary embodiment of the invention; and

FIG. 6 shows a memory arrangement according to another exemplary embodiment of the invention.

### DESCRIPTION OF THE INVENTION

The aim of a shift operation is for the data which is to be shifted no longer to be located at the original memory location after its storage location has been changed, or expressed in other words after the data which is being stored in a new memory location has been copied. For this reason, the operation of “shifting” is obviously composed of the two successive operations of “copying” and “deletion”. Since every operation which is carried out on a data record can lead to data losses, it is important to check that the data record at the new memory location is correct, before this data is deleted at the old memory location, in order to allow the data record to be recreated if required.

On the other hand, the operation of “shifting” is used when the aim is to ensure that the data is not kept, or expressed in other words, stored at two memory locations at the same time.

For this reason, it is desirable for the operation of “shifting” not to be interrupted at a time at which the data record is still located at both memory locations at the same time, or expressed in other words is stored at both memory locations at the same time, and before the data record at the original memory location can be deleted.

As described above, the operation of “shifting” normally comprises the two operations of “copying” and “deletion”, which are carried out immediately successively.

It would in principle be possible to copy the data which is to be shifted byte-by-byte or bit-by-bit and to delete each byte or bit, respectively, immediately in the existing data record, in order to ensure that the data is not present in its entirety at both memory locations, but this option involves an increased risk of data loss.

The combination of the operations of “copying” and “deletion” is normally a good method provided that it is ensured that the operation is not interrupted after the copying process, in order to prevent deletion of the data record at the original memory location.

However, this interruption is in fact possible without any problems in the case of replaceable memory media.

If the replaceable memory medium is removed while carrying out the operation of “shifting”, then the operation is interrupted. If the operation is interrupted at the “right” time, then the user can deliberately copy the data. The “right” time can be calculated by the user, or can be determined by trial and error.

However, there are cases in which the copying of a specific data record should be prevented by the operating system being used, in general the software being used.

The increased use of replaceable memory media such as multimedia cards, secure digital cards, compact-flash cards, USB sticks, floppy disks, CD-RWs, smart cards, etc. has resulted in a considerable increase in the risk of deliberate interruption of the operation of “shifting”.

According to one exemplary embodiment of the invention, the operation of “shifting” of data is made more robust to errors, for example relating to the risk of interruption of the operation, avoiding the data which is to be shifted being present at the same time at both memory locations, the original memory location and the destination memory location.

The described embodiments apply, to the extent that this makes sense, in the same way both to the memory arrangement, to the memory devices, to the methods for shifting of data from a first memory device to a second memory device, and to the computer program elements.

According to one exemplary embodiment of the invention, a memory arrangement has a first memory device and a second memory device. The first memory device has a first memory storing data which is to be shifted, as well as an encrypting unit encrypting data on the basis of an asymmetric encryption method using the public cryptographic key of a second memory device to which the data which is to be shifted and is stored in the first memory is to be shifted. Furthermore, the first memory device optionally has a first hash-value generating unit generating a first hash value which is formed over at least some of the data which is to be shifted. In addition, the first memory device has a shift message generating unit generating at least one shift message. The at least one shift message has the data which is to be shifted and is encrypted with the public cryptographic key of the second memory device and, possibly, the first hash value for example. Furthermore, the first memory device has a deleting unit deleting from the first memory the stored data which is to be shifted, once the data which is to be shifted and is encrypted with the public cryptographic key of the second memory device has been formed, and has a copying unit copying the at least one shift message to the second memory device or to a third memory device. The second memory device has a receiving unit receiving at least one shift message from the first memory device or from the third memory device, with the at least one shift message having data which is to be shifted and is encrypted with the public cryptographic key of the second memory device, and, possibly, the first hash value for example. Furthermore, the second memory device has a decrypting unit decrypting the encrypted data which is to be shifted, using the secret key of the second memory device and, optionally, a second hash-value generating unit generating a second hash value which is formed over at least some of the decrypted data. Furthermore, a determination unit can be provided in the second memory device in order to determine whether the first hash value matches the second hash value. Furthermore, a second memory storing the decrypted data is provided in the second memory device.

According to another exemplary embodiment of the invention, one memory device has a memory storing the data which is to be shifted, as well as an encrypting unit encrypting data on the basis of an asymmetric encryption method using the public cryptographic key of a second memory device to which the data which is to be shifted and is stored in the memory is to be shifted. Furthermore, the memory device optionally has a first hash-value generating unit generating a first hash value, which is formed over at least some of the data which is to be shifted. In addition, the memory device has a shift message generating unit generating at least one shift message, with the at least one shift message having the data which is to be shifted and is encrypted with the public cryptographic key of the second memory device and, possibly, the first hash value for example. In addition, a deleting unit is provided for deleting from the memory the stored data which is to be shifted, once the data which is to be shifted and is encrypted with the public cryptographic key of the second memory device has been formed, and has a copying unit copying the at least one shift message to the second memory device or to a third memory device, in the memory device.

According to another exemplary embodiment of the invention, a memory device is provided having a receiver unit receiving at least one shift message from the first memory device or from a third memory device, with the at least one shift message having data which is to be shifted and is encrypted with the public cryptographic key of the second memory device and, possibly, a first hash value, which is formed over at least some of the data which is to be shifted, for example, as well as having a decrypting unit decrypting the encrypted data which is to be shifted, using the secret key of the second memory device. In addition, the memory device optionally has a second hash-value generating unit generating a second hash value, which is formed over at least some of the decrypted data. Furthermore, a determination unit can be provided in the memory device, in order to determine whether the first hash value matches the second hash value. In addition, a memory storing the decrypted data is provided in the memory device.

In the case of a method for shifting of data from a first memory device to a second memory device according to one exemplary embodiment of the invention, data which is to be shifted and is stored in a first memory of the first memory device is encrypted on the basis of an asymmetric encryption method using the public cryptographic key of a second memory device to which the data which is to be shifted and is stored in the first memory is to be shifted, and a first hash value can be formed over at least some of the data which is to be shifted. Furthermore, at least one shift message is produced, with the at least one shift message having the data which is to be shifted and is encrypted with the public cryptographic key of the second memory device, and possibly having the first hash value for example, and with the stored data which is to be shifted being deleted from the first memory once the data which is to be shifted and is encrypted with the public cryptographic key of the second memory device has been formed.

The at least one shift message is copied to the second memory device or to a third memory device, and the at least one shift message is received by the second memory device or by the third memory device. Furthermore, the encrypted data which is to be shifted is decrypted using the secret key of the second memory device, and a second hash value can be formed over at least some of the decrypted data. According to one embodiment of the invention, the method determines whether the first hash value matches the second hash value and, for example, if the first hash value matches the second hash value, the decrypted data is stored in a second memory in the second memory device.

According to another exemplary embodiment of the invention, in the case of a method for shifting of data from a first memory device to a second memory device, data which is to be shifted and is stored in a first memory of a first memory device is encrypted on the basis of an asymmetric encryption method using the public cryptographic key of a second memory device to which the data which is to be shifted and is stored in the first memory is to be shifted, and a first hash value can be formed over at least some of the data which is to be shifted. At least one shift message is generated, with the at least one shift message having the data which is to be shifted and is encrypted with the public cryptographic key of the second memory device and, possibly having the first hash value for example. The stored data which is to be shifted is deleted from the first memory once the data which is to be shifted and is encrypted with the public cryptographic key of the second memory device has been formed, and the at least one shift message is copied to the second memory device or to a third memory device.

According to another exemplary embodiment of the invention, in the case of a method for shifting of data from a first memory device to a second memory device, at least one shift message is received by the second memory device or by a third memory device, with the at least one shift message having the data which is to be shifted and is encrypted with the public cryptographic key of the second memory device and, possibly having a first hash value, which is formed over at least some of the data which is to be shifted, for example. The encrypted data which is to be shifted is decrypted using the secret key of the second memory device, and a second hash value can be formed over at least some of the decrypted data. Furthermore, it is possible to determine whether the first hash value matches the second hash value and, for example if the first hash value matches the second hash value, the decrypted data is stored in a second memory in the second memory device.

Furthermore, computer program elements are provided for shifting of data from a first memory device to a second memory device which, if said computer program elements are in the form of a processor, have the processes of at least one of the methods described above.

The third memory device clearly represents only a transport medium for transportation of the data which is to be shifted to the second memory device, representing the actual shift destination for the data which is to be shifted.

The encrypting unit and/or the decrypting unit need not necessarily be part of the hardware of the memory unit. The memory devices should be understood as meaning that, for example, a memory device for the purposes of this description can also be represented by a personal computer, a laptop, a notebook or a personal digital assistant. The encrypting unit and/or the decrypting unit may also be in the form of a computer program, that is to say software for the purposes of a function which is provided by the operating system or by software at the application level. Corresponding statements apply to the hash-value generating unit, which will be explained in more detail in the following text.

In one embodiment of the invention, authentication of the second memory device is provided before the encryption of the data which is to be shifted, thus ensuring that the key which is used for encryption is actually a valid key for the second memory device. In this case, the key which is used for encryption may include a unique identification (also referred to as a tag). The first memory device (for example an appropriately designed computer program in the first memory device) checks the unique identification before the encryption of the data which is to be shifted, and compares this with the identification stored in the key, and, for example, does not encrypt the data which is to be shifted unless the authentication of the second memory device was successful.

The first memory device and the second memory device may be different memory media or else the same memory medium, in which case, in the latter situation all that is intended is that data be shifted from a first memory location in the memory medium to a different memory location in the same memory medium.

In the situation where the memory devices are located in two memory media which are separate from one another but are coupled by means of a communication link, at least one of the two memory devices may be provided in a replaceable memory medium, for example the replaceable memory medium may be a multimedia card, a secure digital card, a compact flash card, a USB stick, a floppy disk, a CD-RW (Compact Disc Read Write), a smart card, or in general a memory medium which is coupled to some other electronic appliance which, for example, has a processor, and may have the other memory device, in which case the coupling may be designed to be detachable. The coupling may be wire-based or else wire-free, for example being provided by means of a radio link. The memory devices and/or the electronic appliance or appliances containing the memory devices have/has appropriately designed communication interface units implementing the appropriate communication protocols which are required for communication and thus for data interchange. By way of example, a serial interface connection, for example, RS-232, USB, UART or a parallel interface connection can be provided as a wire-based communication link. A radio communication link based on Firewire or wireless LAN (Wireless Local Area Network), for example IEEE 802.11 or HIPERLAN, or else a mobile radio communication link, for example configured in accordance with UMTS, GPRS, CDMA2000, etc., may be provided as the radio communication link.

Alternatively, any other suitable communication link may be provided.

For the purposes of this description, the expression shifting of data means, for example, an operation which essentially comprises two operation elements, the operation elements of “copying” of the data and “deletion” of the data, with the operation elements being carried out successively. During the operation of “shifting”, the stored data is shifted from one memory location and thus from a first memory device to a different memory location and thus to a second memory device. The aim of this operation is for the data which is to be shifted no longer to be located at the original memory location after its storage location has been changed, or expressed in other words after the data which is then being stored in a new memory location has been copied.

The use of an asymmetric encryption method using the public key of the “destination” memory device makes it possible for the unencrypted data to be deleted immediately from the first memory once the data which is to be shifted has been encrypted even before the copying process, expressed in other words the transmission of the encrypted data which is to be shifted to the “destination” memory device has been successfully completed, since the encrypted data which is to be shifted is still available in the first memory device for the “receiver”, expressed in other words the “destination” memory device. This means that the copying of the encrypted data which is to be shifted to the “destination” memory device could be repeated as often as required until the process has been successfully completed. In consequence, even undesirable interruption of the copying process cannot lead to a loss of data. This also ensures that, after the data which is to be shifted has been deleted from the memory in the first memory device, the first memory device and its user can no longer access the data which is to be shifted, since only the data which is to be shifted and is encrypted with the public key of the second memory device is still available in the first memory device, which cannot be decrypted again by the first memory device and therefore cannot be processed further in a worthwhile manner by it anymore, for example if the data is in the form of media data, for example audio data, video data, still-image data, text data, computer programs etc. This provides a copying protection mechanism in a simple manner, which can no longer be bypassed by suitable adapted interruption of the shift process. In one refinement of the invention, the deletion is in the form of so-called secure deletion, that is to say for example the data to be deleted is overwritten with other undefined (random) data (this deletion process is also referred to, for example, as “wipe out”). In this case, not only is an addressing bit deleted, but all of the bits to be deleted are overwritten with other undefined data.

Embodiments of the invention may be provided in software, that is to say by means of one or more appropriately designed computer programs, in hardware, that is to say by means of one or more appropriately designed electronic circuits, by means of programmable electronic modules, for example an ASIC or an FPGA, or in a hybrid form, that is to say subdivided as required partially in hardware, software and/or by means of programmable electronic modules.

According to one embodiment of the invention, the first memory device has a first hash-value generating unit for generating a first hash value which is formed over at least some of the data which is to be shifted. The shift message generating unit according to this requirement of the invention is designed to produce the at least one shift message, with the at least one shift message having the data which is to be shifted and is encrypted with the public cryptographic key of the second memory device, and having the first hash value.

In this context, it should be noted that the first hash-value generating unit does not necessarily need to be provided in the first memory device. The first hash-value generating unit can be provided in any device which is authorized to read the data. Expressed in other words, the hash-value formation can also be carried out by any other desired entity which is authorized to read the data.

The shift message may have the first hash value.

According to another embodiment of the invention, the second memory device has a second hash-value generating unit generating a second hash value which is formed over at least some of the decrypted data. Furthermore, the second memory device may have a determination unit in order to determine whether the first hash value matches the second hash value.

The use of the hash values additionally ensures integrity when the hash values cannot be changed (read only), of the shifted data for the receiver, expressed in other words for the second memory device.

If the respective hash value is additionally encrypted with the private key of the transmitter, a so-called digital signature is formed. This ensures not only the integrity but likewise the authenticity of the message, expressed in other words of the shifted data. A digital signature may be changed, but automatically loses its validity in the process.

The shift message generating unit generating the at least one shift message may be configured in such a manner that the data which is to be shifted and is encrypted with the public cryptographic key of the second memory device is contained together with the first hash value in a common shift message.

Another embodiment of the invention provides for the shift message generating unit generating the at least one shift message to be configured in such a manner that the data which is to be shifted and is encrypted with the public cryptographic key of the second memory device is contained in a first shift message, and for the first hash value to be contained in a second shift message.

Expressed in other words, this means that the encrypted data which is to be shifted and the first hash value can be contained in a common shift message, or in different shift messages.

The first hash value can be encrypted with the public cryptographic key of the second memory device.

Additionally or alternatively, the first hash value can be encrypted with the private key of the transmitter. This encrypted first hash value can subsequently be decrypted by any desired holder of the associated public key. This ensures that only the holder of the private key (that is to say the “right” transmitter) has actually formed the first hash value, and has thus sent the message.

This increases the cryptographic security of the mechanism even further.

According to one embodiment of the invention, the first hash-value generating unit is configured to generate the first hash value using a secure hash method.

According to one embodiment of the invention, the second hash-value generating unit is configured to generate the second hash value using a secure hash method.

Furthermore, one embodiment of the invention provides for the first hash-value generating unit and/or the second hash-value generating unit to be configured to generate the first hash value and/or the second hash value using one of the following secure hash methods: MD4, MD5, RIPEMD, SHA-1.

The encrypting unit can be configured to encrypt data using the RSA encryption method, and/or using the ElGamal encryption method.

Furthermore, the decrypting unit can be configured to decrypt the data using the RSA encryption method and/or using the ElGamal encryption method.

It should be noted that any other suitable asymmetric encryption method can be used without any problems in an alternative embodiment of the invention.

According to another embodiment of the invention, a certificate checking unit is provided in order to check a certificate for a public cryptographic key. When a certificate is used, this ensures, for example, the trustworthiness of the public cryptographic key for the second memory device.

Furthermore, the first memory device may have a receiving unit receiving the public cryptographic key of the second memory device.

Furthermore, the first memory device may have a transmission unit transmitting a key confirmation message, by means of which the reception of the public cryptographic key of the second memory device is confirmed, to the transmitter from which the public cryptographic key of the second memory device has been received.

During this procedure, in addition to the transmitter key confirmation message, the first memory device explicitly notifies the fact that the first memory device has correctly received the key confirmation message, and thus the public key.

According to another embodiment of the invention, the second memory device has a transmission unit transmitting a shift confirmation message, by means of which the completion of the shifting of the data which is to be shifted is confirmed, to the first memory device.

This mechanism ensures that the first memory device is explicitly informed of the successful completion of the shift operation, in response to which the first memory device can, for example, delete the encrypted data, which is to be shifted, in order to save memory space, from the memory in the first memory device.

According to another embodiment of the invention, the deleting unit is configured in such a manner that the stored data which is to be shifted is deleted from the first memory before the at least one shift message has been transmitted.

Furthermore, the deleting unit can be configured in such a manner that the stored data which is to be shifted is deleted from the first memory before the at least one shift message has been deleted.

According to one development of the invention, the deleting unit is configured to delete the at least one shift message.

Furthermore, the deleting unit can be configured in such a manner that the at least one shift message is deleted after the first memory device has received the shift confirmation message.

Further exemplary embodiments of the invention will be explained in more detail in the following text, and are illustrated in the figures.

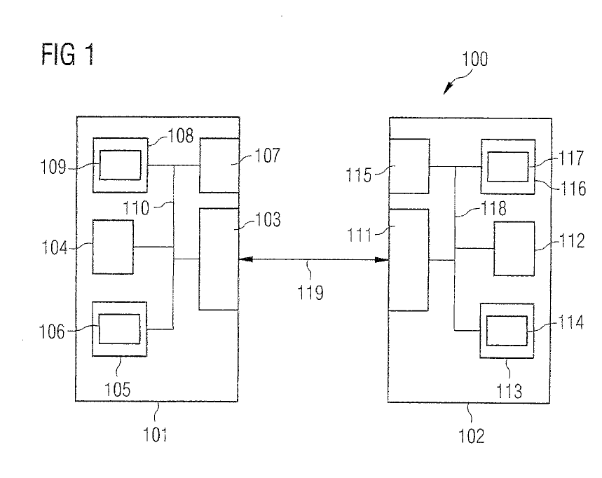

FIG. 1 shows a memory arrangement 100 having a personal computer 101 as a first memory device, and having a USB stick 102 as a second memory device.

The personal computer 101 has a USB interface 103 as well as a central processing unit (CPU) 104 and a program code memory 105 for storage of program codes 106 to be run by means of the CPU 104. Furthermore, the personal computer 101 has a crypto-logic unit 107, which may be in the form of software or in the form of a dedicated crypto-controller, as well as a data memory 108 in which data is stored, for example media data 109, for example audio data (for example MP3 files), video data (for example MPEG files), still-image data (for example JPEG files), text data (for example Winword files, table calculation files, presentation files). The data memory 108 is, for example, a non-volatile data memory, for example a flash data memory (for example with floating gate memory cells, with trapping layer memory cells, etc.). The individual components described above are coupled to one another by means of a data and control bus 110. Furthermore, further normal components are provided in the personal computer 101, such as additional communication interfaces, driver units etc., although these are not described in detail in order to make the description more easily understood.

The USB stick 102 likewise has a USB interface 111. Furthermore, a microprocessor 112 is provided in the USB stick 102, for example in order to control the various operations of the USB stick 102 (for example programming (writing), reading, deletion, shifting of data), as well as a program code memory 113 storing of a control program code 114 to be run by means of the microprocessor 112. Furthermore, a crypto-logic unit 115 is provided in the USB stick 102 and may be in the form of software or a dedicated crypto-controller, as well as a data memory 116 in which data is stored, for example media data 117, for example audio data (for example MP3 files), video data (for example MPEG files), still-image data (for example JPEG files), text data (for example Winword files, table calculation files, presentation files). The data memory 116 is, for example, a non-volatile data memory, for example a flash data memory (for example with floating gate memory cells, with trapping layer memory cells, etc.). The individual components described above are coupled to one another by means of a data and control bus 118.

The personal computer 101 and the USB stick 102 are connected by means of their respective USB interface 103, 111, such that data can be transmitted 119 between them.

This exemplary embodiment of the invention is based on the assumption that a data record, for example the media data 109 or a portion of the media data 109 is located in the first memory device, that is to say in this example the data memory 108 in the personal computer 101, expressed in other words it is stored there, with the data record being intended to be shifted to the second memory device, on the basis of this exemplary embodiment of the invention to the USB stick 102, where, for example, it is intended to be stored as shifted media data in the data memory 116 in the USB stick 102.

The USB interface that is used can be disconnected, expressed in other words detached, very easily as a plug connection.

In general, the interface which is used in each of the exemplary embodiments can be disconnected very easily.

As described above, both the personal computer 101 and the USB stick 102 have a respective logic unit (for example the crypto-logic unit 107 or 115, respectively), which is able, that is to say configured, to carry out an asymmetric encryption method.

An asymmetric encryption method is, for example, a method in which two different cryptographic keys are used.

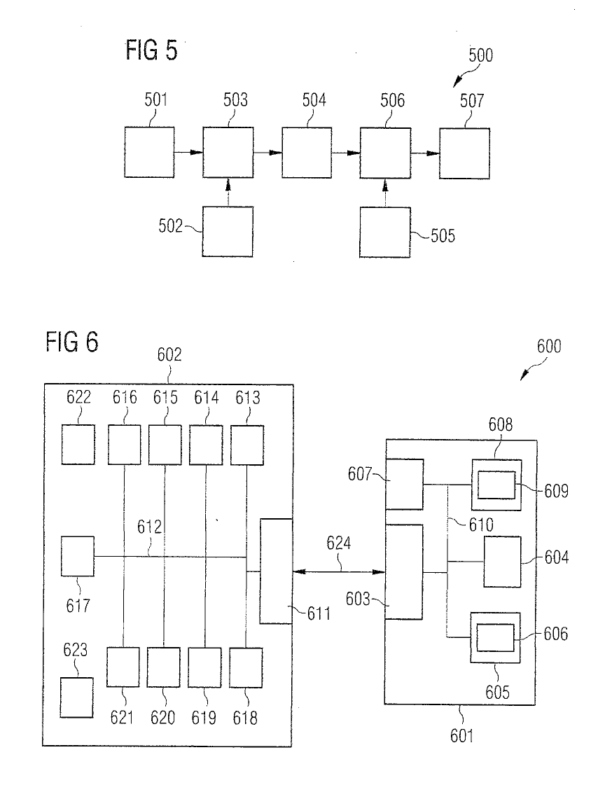

The fundamental principle of an asymmetric encryption method that is used for the purposes of the exemplary embodiments is illustrated in a block diagram 500 in FIG. 5.

Encryption (block 503) is carried out on various data items 501 which are stored in the data memory 108 in the personal computer 101, using a public cryptographic key 502 for the USB stick 102 on the basis of an asymmetric encryption method, for example on the basis of the RSA encryption method or on the basis of the ElGamal encryption method, by which means encrypted data 504 that is to be shifted is formed.

The encrypted data 504 which is to be shifted is transmitted in a shift message, which will be explained in more detail in the following text, from the personal computer 101, in general from the first memory device, to the USB stick 102, in general to the second memory device.

Once the shift message has been received in the USB stick 102, the encrypted data 504 which is to be shifted is determined from the shift message and is decrypted (block 506) using the private cryptographic key 505 (which corresponds to the public cryptographic key 502 for the USB stick 102) for the USB stick 102 on the basis of the asymmetric encryption method being used, and this results in decrypted data 507, which is to be shifted, being formed which is identical to the data 501 which is to be shifted on successful decryption. The decrypted data 507 which is to be shifted can now be stored in the data memory 116 in the USB stick 102.

A respective public cryptographic key for an asymmetric cryptographic key pair is used only for encryption of a data record, but encrypted data cannot be decrypted again with the aid of the public cryptographic key. A respective private cryptographic key (also referred to as a secret key) which is associated with the respective public cryptographic key for an asymmetric cryptographic key pair can be used as a single cryptographic key for decryption of the data which has been encrypted by means of the associated public cryptographic key. The public cryptographic key may be published, such as it is freely accessible to any third party. Its free distribution to third parties does not represent a security risk since it can be used only for encryption. If someone has the public cryptographic key, he is able to encrypt a data record for the holder of the associated private cryptographic key. In order to ensure that the public cryptographic key is actually associated with the user, indicating that this is his public cryptographic key, one embodiment of the invention provides for the public cryptographic key to have an associated key certificate which is formed by a certification instance, and for this to be provided to the respective third party together with the respective public cryptographic key.

Furthermore, according to this exemplary embodiment of the invention, the assumption is made that the media data 117 which is stored in the data memory 108 in the personal computer 101 includes audio data (coded in accordance with MP3-Standard) which is to be shifted and is intended to be shifted to the data memory 116 in the USB stick 102. Expressed in other words, the aim is to copy the audio data from the data memory 108 in the personal computer 101 to the data memory 116 in the USB stick 102, and also to delete the audio data from the data memory 108 in the personal computer 101. It should be noted that any type of data, for example any undefined type of media data, for example including all of the data record that is stored in the data memory 108 in the personal computer 101, may be shifted.

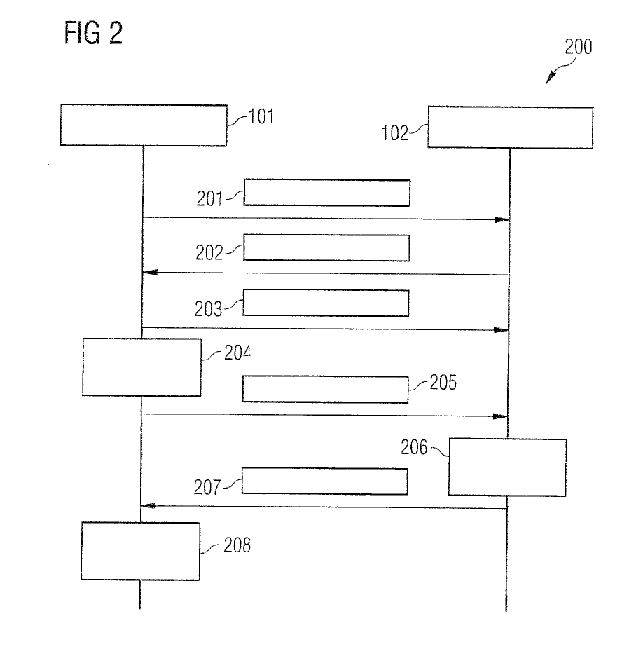

In order to shift the audio data from the data memory 108 in the personal computer 101 to the data memory 116 in the USB stick 102, the personal computer 101 requests this audio data in a first process (if it does not yet have the public cryptographic key for the USB stick 102) from, for example, the USB stick 102 or from a certification instance (not illustrated) which may be provided. According to this exemplary embodiment, this is done by the personal computer 101 generating a key request message 201, by means of which a public cryptographic key which is stated in the key request message 201 is requested, and by this being transmitted to the USB stick 102 by means of the USB interfaces 103, 111 (see message flowchart 200 in FIG. 2).

After reception of the key request message 201, the USB stick 102 reads its requested public cryptographic key and generates a key response message 202, which contains this key, and transmits this (once again by means of the USB interfaces 103, 111) to the personal computer 101. As has been described above, there is an optional provision to use the key response message 202 to transmit to the personal computer 101 a key certificate (not illustrated) which is formed via the requested public cryptographic key.

According to these exemplary embodiments of the invention, the private cryptographic key (which is associated with the requested public cryptographic key) for the USB stick 102 does not leave the USB stick 102 at any time, and is thus protected against unauthorized access.

After reception of the key response message 202, it is thus possible for the personal computer 101 to encrypt the audio data which is to be shifted, with the requested public cryptographic key for the USB stick 102, but it is not possible for the personal computer 101 to itself once again decrypt the audio data which is to be shifted and has been encrypted using the public cryptographic key of the USB stick 102, and thus to itself once again form the audio data from the encrypted audio data which is to be shifted.

In response to correct reception of the key response message 202, the personal computer 101 optionally produces a key confirmation message 203, which confirms correct reception of the requested public cryptographic key for the USB stick 102, and transmits this to the USB stick 102.

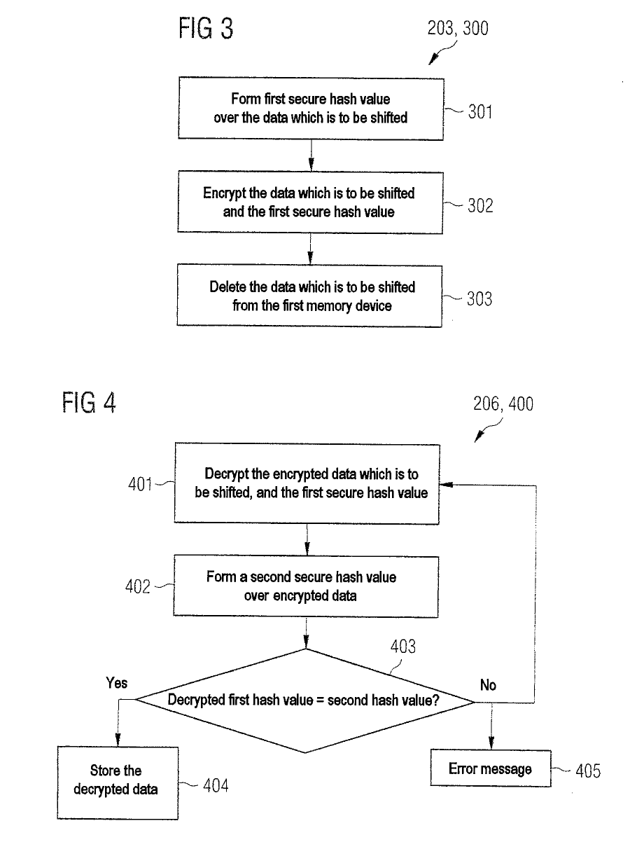

Furthermore, according to this exemplary embodiment of the invention, the personal computer 101 carries out the following processes, which are symbolized by block 204 and are illustrated in detail in the flowchart 300 in FIG. 3.

In a first process, a secure hash value is formed (process 301) over the audio data D which is to be shifted, using a secure hash method, for example using one of the following methods: MD4, MD5, RIPEMD or SHA (for example SHA-1).

Expressed in other words, the personal computer 101 forms a first secure hash value S using the following rule:
S=hash {D}.

The first secure hash value S has a defined length as a function of the hash function being used.

The audio data D which is to be shifted and, if appropriate, the first secure hash value S are then changed to an encrypted data record E, or expressed in other words are encrypted to form the encrypted data E using the following rule (process 302):
E=pK(B) {D +S},

where
pK(B) is the public key for the USB stick 103,
D is the audio data which is to be shifted, and
S is the first secure hash value.

The encryption is carried out in the crypto-logic unit 107 in the personal computer 101, using an asymmetric encryption method, for example the RSA method, the ElGamal method, or any desired variant of these methods. The encryption is carried out using the public key 502 for the USB stick 103.

The encryption process can be checked and repeated until it has been carried out successfully.

The use of the hash function and thus the formation of the first secure hash value S, which is likewise located in the crypto-logic unit 107 in the personal computer 101, is optional.

After the formation of the encrypted data E, the audio data D which is to be shifted is deleted from the data memory 108 in the personal computer 101, for example by using random numbers to overwrite the memory area in which the audio data D which is to be shifted is stored (process 303).

The audio data D which is to be shifted is thus no longer available in the personal computer 101. Furthermore, the encrypted data E cannot be used for the personal computer 101, and is thus useless, since the encrypted data E cannot be decrypted by the personal computer 101, and the audio data D can thus no longer be reconstructed by the personal computer 101.

After the formation of the encrypted data E, and optionally after the deletion of the audio data D which is to be shifted from the data memory 108 in the personal computer 101, the personal computer 101 forms a shift message 205 which includes the encrypted data E.

The shift message 205 is copied from the personal computer 101 to the USB stick (operation of “copying”).

After the completion of the copying process, expressed in other words once the USB stick 102 has received the shift message 205, the USB stick 102 determines the encrypted data E from the shift message 205, and the USB stick 102 carries out the following processes, according to this exemplary embodiment of the invention, which are symbolized by the block 206, and are illustrated in detail in a flowchart 400 in FIG. 4.

The encrypted data E is decrypted by the crypto-logic unit 115 in the USB stick 102 (process 401) on the basis of the respectively used asymmetric encryption method using the private (secret) cryptographic key 505 for the USB stick 102. Successful decryption of the encrypted data E results in the decrypted audio data D′, which is identical to the audio data D which is to be shifted, if appropriate as well as the decrypted first secure hash value S′, which is identical to the first secure hash value S.

Expressed in other words, the decrypted audio data D′ and the decrypted first secure hash value S′ are formed using the following rule:
D′+S′=sK(B){E},

where
sK(B) is the private key for the USB stick 103,
D′ is the decrypted audio data, and
S′ is the decrypted first secure hash value.

The USB stick 102 then checks whether the decrypted first secure hash value S′ matches the decrypted audio data D′.

For example, this is done by the crypto-logic unit 115 in the USB stick 102 using the decrypted audio data D′ to produce a second secure hash value F (process 402), using the respective secure hash method that is in each case used to form the first secure hash value, that is to say for example using one of the following methods: MD4, MD5, RIPEMD or SHA (for example SHA-1).

Expressed in other words, the USB stick 102 forms the second secure hash value F using the following rule:
F=hash {D′}.

In a checking process 403, the microprocessor 112, for example, in the USB stick 102 or the crypto-logic unit 115 in the USB stick 102 then checks whether the second secure hash value F is the same as the decrypted first secure hash value S′.

If this is the case, then the decrypted audio data D′ is stored in the data memory 116 in the USB stick 102.

However, if this is not the case and an error has thus occurred, then the decryption process (process 401) and/or the copying process (that is to say the transmission of the shift message 205) can if required be repeated until a positive result is obtained, or expressed in other words until, for example, the respective second secure hash value F is the same as the respective decrypted first secure hash value S′. Alternatively or additionally, an error message can also be produced (step 405), and, if required, the method can be ended.

When the copying process has been successfully completed on the basis of correct decryption and positive checking of the hash values, then the USB stick 102 optionally produces a shift confirmation message 207, which indicates that the copying process has been successfully completed by the USB stick 102. The shift confirmation message 207 is transmitted to the personal computer 101. According to this exemplary embodiment of the invention, the shift confirmation message 207 additionally includes the decrypted first secure hash value S′, in order that the personal computer 101 can also be certain that the audio data D which is to be shifted has been correctly reconstructed again by the USB stick 102.

In response to the reception of the shift confirmation message 207 and after successfully checking that the decrypted first secure hash value S′ is identical to the first secure hash value S, the personal computer 101 deletes the encrypted data E (process 208 in FIG. 2).

After the deletion of the encrypted data E, the entire process of “shifting” of the audio data D which is to be shifted is complete.

It should be noted that the transmission can also take place in the opposite direction from the USB stick 102 to the personal computer 101, that is to say the data which is to be shifted can, in an alternative embodiment, also be transmitted from the data memory 116 in the USB stick 102 to the data memory 108 in the personal computer 101. In this case, the encryption is carried out in the USB stick 102, and the decryption in the personal computer 101.

According to another exemplary embodiment of the invention, a memory arrangement 600 (see FIG. 6) is provided, in which the first memory device is a communication terminal 601, for example a mobile radio communication terminal, configured for example in accordance with a communication standard for the second, third or subsequent generation, for example configured in accordance with the GSM, UMTS or CDMA2000 communication standard.

The second memory device according to this exemplary embodiment of the invention is a smart card 602, which is located in the mobile radio communication terminal 601 and, for example is configured to communicate with the mobile radio communication terminal 601 using the UART communication protocol.

The procedure in this exemplary embodiment of the invention corresponds essentially to that for the first exemplary embodiment of the invention as described above, so that only the differences from the first exemplary embodiment of the invention will be described in the following text. The other method processes and mechanisms are provided in an analogous manner to the first exemplary embodiment of the invention.

The communication interface of the mobile radio communication terminal 601 and of the smart card 602 is not configured in accordance with the USB Standard, but for communication in accordance with the UART Standard (Universal Asynchronous Receiver Transmitter).

The mobile radio communication terminal 601 which has been configured in accordance with the UMTS communication standard on the basis of this exemplary embodiment of the invention has a UART interface 603 as well as a central processing unit (CPU) 604 and a program code memory 605 for storage of program codes 606 which are intended to be run by means of the CPU 604. Furthermore, the mobile radio communication terminal 601 has a crypto-logic unit 607, which may be in the form of software or a dedicated crypto-controller, as well as a data memory 608 in which data is stored, for example media data 609, for example audio data (for example, MP3 files), video data (for example MPEG files), still-image data (for example JPEG files), text data (for example Winword files, table calculation files, presentation files). By way of example, the data memory 608 is a non-volatile data memory, for example a flash data memory (for example with floating gate memory cells, with trapping layer memory cells, etc.). The individual components described above are coupled to one another by means of a data and control bus 610. Furthermore, further components which are normal in their own right are provided in the mobile radio communication terminal 601, such as additional communication interfaces, driver units, a mobile radio antenna, keys, a display unit such as a screen etc., although these are not described in detail in order to make the description more easily understood.

In addition to the UART communication interface 611, the smart card 602 has, inter alia, the following components which are coupled to one another by means of a data and control bus 612:
a read only memory 613 (ROM) with a size of 240 kbytes, for storage of program code for control of the smart card,
a random access memory 614 (RAM) with a size of 16 kbytes.
a non-volatile data memory 615 (electrically erasable read only memory, EEPROM) for storage of data, for example for storage of media data and/or of program code, in this exemplary embodiment with a size of 912 kbytes,
a scalable clock generator 616 for provision of one or more clock signals for the respective components which require a clock signal for their operation,
a central processing unit 617, according to this embodiment of 32-bit CPU with a memory management and protection unit,
a random number generator 618,
a DES accelerator component 619 for carrying out a symmetrical encryption method, according to this exemplary embodiment of the invention for carrying out the DES method (data encryption standard),
a crypto-logic unit 620 for carrying out an asymmetric encryption method such as an RSA method or an ElGamal method and possibly for carrying out a secure hash method,
a 16-bit timer 621.

Furthermore, at least one sensor and/or filter element 622 is provided in the smart card 602, in order to provide electrical variables which are used to control the voltage that is used, the clock or to reset of individual components of the smart card 602, and/or to detect environmental conditions, for example the ambient temperature.

Furthermore, a voltage regulator 623 is provided in the smart card 602.

The mobile radio communication terminal 601 and the smart card 602 are connected by means of their respective UART interface, thus allowing data transmission 624 between them.

This exemplary embodiment of the invention is based on the assumption that the media data 609 which is stored in the data memory 608 in the mobile radio communication terminal 601 contains video data which is to be shifted (for example a video file coded using an MPEG Standard, for example using an MPEG4 Standard), which is intended to be shifted to the data memory 615 in the smart card 602. Expressed in other words, the aim is to copy the video data from the data memory 608 in the mobile radio communication terminal 601 to the data memory 615 in the smart card 602, and to also delete the video data from the data memory 608 in the mobile radio communication terminal 601. It should be noted that any type of data, for example any desired type of media data, for example including the entire data record which is stored in the data memory 608 in the mobile radio communication terminal 601, can be shifted.

According to this exemplary embodiment of the invention, a mobile radio subscriber thus wishes to transmit the video data from the mobile radio communication terminal 601 to the smart card 602 that is located in it, in order to allow the video data to still be used with the same smart card 602 after replacement of the mobile radio communication terminal 601.

The method described above is used analogously to that in the second exemplary embodiment of the invention in order to transmit the data.

The method according to the second exemplary embodiment of the invention has the following effects, by way of example, and overcomes at least some of the risks described in the following text:
both memory media contain logic units which can control the method procedure;
both memory devices (mobile radio communication terminal and smart card) have components which are configured to carry out an asymmetric encryption method, for example an RSA method;
a smart card could be removed in a simple manner from the mobile radio communication terminal during a “shift” operation, which would result in the operation of “shifting” being interrupted;
the physical interface between the mobile radio communication terminal and the smart card can be physically attacked very easily;
a utilization chain could be interrupted by the copying of the file;
for example, an MPEG4 video file can also be used incompletely, and the time of interruption can thus be chosen fairly roughly;
the user of a copy of the file would profit if copying is actually not envisaged (protected content).

One exemplary embodiment of the invention makes use of the fact that ever more replaceable storage media have safety logic (for example a crypto-logic unit), as is the case, for example, with smart cards.

The procedure described above carries out the operation of “shifting” of data more securely than the conventional procedures. The effects of freedom from interruption are combined with high data security. As described above, an uninterruptible method is provided for the shifting of data in which reproduction of the data is ensured despite interruption of the operation and a loss of data associated with this, without allowing unauthorized multiple use of the data at two memory locations.

According to one exemplary embodiment of the invention, the data is transmitted from the first memory device to the second memory device via the interface only in encrypted form. In the case of a removable memory medium, for example in the case of a smart card or a memory card or a memory stick (such as a USB stick), the interface between the two memory devices is physically accessible in a simple manner, and can thus be attacked in a simple manner. According to one exemplary embodiment of the invention, an attack on the interfaces is made considerably more difficult, or is even prevented.

The memory devices may be configured as required and should only have a memory for storage of data as well as a crypto unit, for example an encrypting unit for carrying out asymmetric encryption of data.

The following features of exemplary embodiments of the invention should also be noted:
cryptographic logic units (also referred to as crypto-logic units) which are provided in the memory devices are used; it should be noted that the memory devices are not necessarily restricted to an apparatus in which the respective cryptographic logic unit is integrated together with the memory in a housing. The respective cryptographic logic unit may also be located outside the housing of the memory, or expressed in other words may be arranged there. The respective cryptographic logic unit should, however, have access to the memory and the user should have trust in the respective cryptographic logic unit;
an asymmetric encryption method is used for shifting of data records; one embodiment of the invention provides for an external cryptographic logic unit which is connected to the memory units to encrypt the actual payload data using a symmetrical key and for only this symmetrical key to be encrypted with an asymmetric method. This hybrid method has the effect that it operates considerably more quickly; however, it is necessary to have more confidence in the encryption unit that it will not interrupt the usage chain;
the method offers both data security by checks at a suitable point, the transmission of the check results, and the capabilities for data reproduction at any desired time.

What is claimed is:

1. A memory arrangement, comprising:
a first memory device, which comprises:
a first memory that stores data which is to be shifted;
an encrypting unit that encrypts data based on an asymmetric encryption method using a public cryptographic key of a second memory device to which the data which is to be shifted and is stored in the first memory is to be shifted;
a shift message generating unit that generates at least one shift message having the data which is to be shifted and is encrypted with the public cryptographic key of the second memory device;
a deleting unit that deletes from the first memory the stored data which is to be shifted once the data which is to be shifted and is encrypted with the public cryptographic key of the second memory device has been formed; and
a copying unit that copies the at least one shift message to the second memory device or to a third memory device, with the data which is to be shifted no longer being available in the first memory from a time before the copying of the shift message to the second memory device or to the third memory device;
a second memory device, which comprises:
a receiver unit that receives at least one shift message from the first memory device or from the third memory device, with the at least one shift message having data which is to be shifted and is encrypted with the public cryptographic key of the second memory device;
a decrypting unit that decrypts the encrypted data using a secret key of the second memory device; and
a second memory that stores the decrypted data.

2. The memory arrangement as claimed in claim 1,
wherein the first memory device has a first hash-value generating unit that generates a first hash value which is formed over at least some of the data which is to be shifted, and
wherein the shift message generating unit generates the at least one shift message, with the at least one shift message having the first hash value and the data which is to be shifted and is encrypted with the public cryptographic key of the second memory device.

3. The memory arrangement as claimed in claim 1, wherein the shift message has the first hash value.

4. The memory arrangement as claimed in claim 3, wherein the second memory device further comprises:
a second hash-value generating unit that generates a second hash value which is formed over at least some of the decrypted data; and
a determination unit that determines whether the first hash value matches the second hash value.

5. The memory arrangement as claimed in claim 2, wherein the shift message generating unit generates the at least one shift message such that the first hash value and the data which is to be shifted and is encrypted with the public cryptographic key of the second memory device are contained in a common shift message.

6. The memory arrangement as claimed in claim 2, wherein the shift message generating unit produces the at least one shift message such that:
the data which is to be shifted and is encrypted with the public cryptographic key of the second memory device is contained in a first shift message, and the first hash value is contained in a second shift message.

7. The memory arrangement as claimed in claim 2, wherein the first hash value is encrypted with the public cryptographic key of the second memory device.

8. The memory arrangement as claimed in claim 2, wherein the first hash-value generating unit generates the first hash value using a secure hash method.

9. The memory arrangement as claimed in claim 2, wherein the second hash-value generating unit generates the second hash value using a secure hash method.

10. The memory arrangement as claimed in claim 8, wherein the first hash-value generating unit or the second hash-value generating unit or both generates or generate the first hash value or the second hash value or both using a secure hash method selected from the group consisting of MD4, MD5, RIPEMD, and SHA-1.

11. The memory arrangement as claimed in claim 1, wherein the encrypting unit encrypts the data using an asymmetric encryption method selected from the group consisting of an RSA encryption method and an ElGamal encryption method.

12. The memory arrangement as claimed in claim 1, wherein the decrypting unit decrypts the data using an asymmetric encryption method selected from the group consisting of an RSA encryption method and an ElGamal encryption method.

13. The memory arrangement as claimed in claim 1, further comprising a certificate checking unit that checks a certificate of a public cryptographic key.

14. The memory arrangement as claimed in claim 1, wherein the first memory device has a receiving unit which receives the public cryptographic key of the second memory device.

15. The memory arrangement as claimed in claim 1, wherein the first memory device has a transmission unit which transmits a key confirmation message, by means of which the reception of the public cryptographic key of the second memory device is confirmed, to the transmitter from which the public cryptographic key of the second memory device has been received.

16. The memory arrangement as claimed in claim 1, wherein the second memory device has a transmission unit which transmits a shift confirmation message, by means of which the completion of the shifting of the data which is to be shifted is confirmed, to the first memory device.

17. The memory arrangement as claimed in claim 1, wherein the deleting unit deletes the stored data which is to be shifted, from the first memory, before the at least one shift message has been transmitted.

18. The memory arrangement as claimed in claim 1, wherein the deleting unit deletes the stored data which is to be shifted, from the first memory, before the at least one shift message has been deleted.

19. The memory arrangement as claimed in claim 1, wherein the deleting unit deletes the at least one shift message.

20. The memory arrangement as claimed in claim 16, wherein the deleting unit deletes the at least one shift message after the first memory device has received the shift confirmation message.

21. The memory arrangement as claimed in claim 19, wherein the deleting unit deletes the at least one shift message after the first memory device has received the shift confirmation message.

22. A memory device, comprising:
a memory storing data which is to be shifted;
an encrypting unit that encrypts data based on an asymmetric encryption method using a public cryptographic key of a second memory device to which the data which is to be shifted and is stored in the memory is to be shifted;
a shift message generating unit that generates at least one shift message having the data which is to be shifted and is encrypted with the public cryptographic key of the second memory device;
a deleting unit that deletes from the memory the data which is to be shifted once the data which is to be shifted and is encrypted with the public cryptographic key of the second memory device has been formed; and
a copying unit that copies the at least one shift message to the second memory device or to a third memory device, with the data which is to be shifted no longer being available in the first memory from a time before the copying of the shift message to the second memory device or to the third memory device.

23. The memory device as claimed in claim 22 being a personal computer or a USB stick.

24. The memory device as claimed in claim 22 being a smart card or a communication terminal.

25. A method for shifting data from a first memory device to a second memory device, comprising:
encrypting data which is to be shifted and is stored in a first memory in the first memory device based on an asymmetric encryption method using a public cryptographic key of a second memory device to which the data which is to be shifted and is stored in the first memory is to be shifted;
generating at least one shift message having the data which is to be shifted and is encrypted with the public cryptographic key of the second memory device;
deleting from the first memory the stored data which is to be shifted, once the data which is to be shifted and is encrypted with the public cryptographic key of the second memory device has been formed;
copying the at least one shift message to the second memory device or to a third memory device, with the data which is to be shifted no longer being available in the first memory from a time before the copying of the shift message to the second memory device or to the third memory device;
receiving the at least one shift message by the second memory device or by the third memory device;
decrypting the encrypted data which is to be shifted, using a secret key of the second memory device; and
storing the decrypted data in a second memory in the second memory device.

26. A method for shifting data from a first memory device to a second memory device, comprising:
encrypting data which is to be shifted and is stored in a first memory in the first memory device based on an asymmetric encryption method using a public cryptographic key of a second memory device to which the data which is to be shifted and is stored in the first memory is to be shifted;
generating at least one shift message having the data which is to be shifted and is encrypted with the public cryptographic key of the second memory device;
deleting from the first memory the stored data which is to be shifted, once the data which is to be shifted and is encrypted with the public cryptographic key of the second memory device has been formed; and
copying the at least one shift message to the second memory device or to a third memory device, with the data which is to be shifted no longer being available in the first memory from a time before the copying of the shift message to the second memory device or to the third memory device.

27. A computer program element for shifting of data from a first memory device to a second memory device which, if it is executed by a processor, comprises:
encrypting data which is to be shifted and is stored in a first memory in the first memory device based on an asymmetric encryption method using a public cryptographic key of a second memory device to which the data which is to be shifted and is stored in the first memory is to be shifted;
generating at least one shift message having the data which is to be shifted and is encrypted with the public cryptographic key of the second memory device;
deleting from the first memory the stored data which is to be shifted, once the data which is to be shifted and is encrypted with the public cryptographic key of the second memory device has been formed; and
copying the at least one shift message to the second memory device or to a third memory device, with the data which is to be shifted no longer being available in the first memory from a time before the copying of the shift message to the second memory device or to the third memory device.
